(19) United States
(12) Patent Application Publication
(10) Pub. No.: US 2012/0249206 A1
(43) Pub. Date: Oct. 4, 2012

(54) VARIBLE DELAY CIRCUIT

(75) Inventor: Tsz Shing CHEUNG, Kawasaki (JP)

(73) Assignee: FUJITSU LIMITED, Kawasaki-shi (JP)

(21) Appl. No.: 13/424,980

(22) Filed: Mar. 20, 2012

(30) Foreign Application Priority Data
Apr. 1, 2011 (JP) 2011-081518

(51) Int. Cl. H03H 11/26

(52) U.S. Cl. 327/281; 327/276

(57) ABSTRACT

A variable delay circuit includes delay units connected in series. Each delay unit includes first to third logic gates. The first logic gates are connected in series so that the output of the previous stage is input to one of inputs of the subsequent stage and first control data is input to the other of the inputs. In each stage, one of inputs of the second logic gate is connected to the one of the inputs of the first logic gate and second control data is input to the other of the inputs. The third logic gates are connected in series, the output of the second logic gate is input to third logic gate, and the delay time of a path from one of the inputs to the output and the delay time of a path from the other of the inputs to the output are substantially the same.

### CROSS-REFERENCE TO RELATED APPLICATIONS

This application is based upon and claims the benefit of priority of the prior Japanese Patent Application No. 2011-081518, filed on Apr. 1, 2011, the entire contents of which are incorporated herein by reference.

### FIELD

The embodiments discussed herein are related to a variable delay circuit.

### BACKGROUND

As the performance of data storage devices, such as memory devices and DRAM for a computer, is improved, it is necessary to increase the data rate in signal transmission/reception inside of and outside a device. As the data rate is increased, in order to compensate for a delay in a transfer line, a high-precision variable delay circuit (variable delay circuit) and a delay locked loop (DLL) circuit utilizing a variable delay circuit are required.

The variable delay circuit has various forms. The most general variable delay circuit has a plurality of delay units connected in series and adjusts the number of stages until an input signal is returned by supplying control data indicative of a return position of the input signal to each delay unit.

Each delay unit has first to third logic gates. Each delay unit has the same circuit configuration. The first logic gates are connected in series so that the output of the previous stage is one of inputs of the subsequent stage. In each stage, first control data is input to the other of the inputs of the first logic gate. In each stage, one of inputs of the second logic gate is connected to the input of the first logic gate, and second control data is input to the other of the inputs of the second logic gate. The third logic gates are connected in series so that the output of the subsequent stage is one of inputs of the previous stage, and the output of the second logic gate is input to the other input of the third logic gate in each stage. An input signal travels through the first logic gate of each stage connected in series and enters the third logic gate from the second logic gate in the delay unit in the return position and travels back through the third logic gates connected in series and is output from the third logic gate in the first stage. By specifying the return position with the first and second control data, the delay amount is variable. The first control data supplied to the delay units before the return position brings the first logic gates into a state where the input signal is transmitted and the first control data supplied to the delay units at the return position and after the return position brings the first logic gate into a state where the input signal is cut off. The second control data supplied to the delay unit in the return position brings the second logic gate into a state where the input signal is transmitted to the third logic gate and the second control data supplied to the other delay units brings the second logic gate into a state where the input signal is cut off.

The second logic gate of the delay unit before the return position outputs a signal to the third logic gate that brings a state where it is possible for the third logic gate to transmit the output of the third logic gate of the subsequent stage. The second logic gate of the delay unit at the return position outputs a signal that makes it possible for the third logic gate to bring the third logic gate in the return position into a state where the output of the second logic gate may be transmitted.

When forming the first to third logic gates by multi-input CMOS logic gates, which are fundamental elements, the NAND gates or NOR gates are generally used because of the relationship between the number of transistors and the delay time, and the delay time of the NOR gate is longer compared to the delay time of the NAND gate.

When forming the first to third logic gates of the delay unit by the multi-input CMOS logic gates, there exist differences between delay times from when the input signal is input to a plurality of input terminals until the delayed signal is output to the output nodes. In other words, there exists a delay time difference between input terminals. Due to this difference, the variable delay circuit formed by the CMOS logic gate has a problem that the delay time difference differs from stage to stage. When the delay time difference differs from stage to stage, the precision of the DLL circuit is reduced and the maximum operating frequency and performance of the data storage device are affected.

### RELATED DOCUMENTS

[Patent Document 1] Japanese Laid-open Patent Publication No. 2000-151372

[Patent Document 2] Japanese Laid-open Patent Publication No. H10-322178

[Patent Document 3] Japanese Laid-open Patent Publication No. 2005-051673

### SUMMARY

According to an aspect of the embodiments, a variable delay circuit includes a plurality of delay units connected in series, wherein each delay unit includes first to third logic gates, the first logic gates of the plurality of delay units are connected in series so that the output of the first gate of the previous stage is input to one of inputs of the first gate of the subsequent stage and first control data specifying a return position is input to the other of the inputs of the first gate, in each stage, one of inputs of the second logic gate is connected to the one of the inputs of the first logic gate and second control data specifying a return position is input to the other of the inputs of the second gate, the third logic gates of the plurality of delay units are connected in series so that the output of the subsequent stage is one of inputs of the third logic gates of the previous stage and in each stage, the output of the second logic gate is input to the other of the inputs of the third gate, and in each third logic gate, the delay time of a path from the one of the inputs to the output and the delay time of a path from the other of the inputs to the output are substantially same.

The object and advantages of the embodiments will be realized and attained by means of the elements and combination particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a circuit diagram illustrating a conventional variable delay circuit in which a plurality of delay units, each having three two-input NAND gates is connected in series;

FIG. 2 is a diagram illustrating first and second control data;

FIG. 3 is a circuit diagram illustrating an example of the two-input NAND gate;

FIG. 4 is a diagram illustrating delays at the gates that are passed through when the return position is changed stepwise in the variable delay circuit in FIG. 1;

FIG. 5A and FIG. 5B are diagrams illustrating the delay times HF, LF, HS, LS when the two-input NAND gate of CMOS type in FIG. 3 is manufactured by a typical process, wherein FIG. 5A illustrates the case where the two-input NAND gate is manufactured by a process with a gate length of 90 nm and FIG. 5B illustrates the case where the two-input NAND gate is manufactured by a process with a gate length of 130 nm;

FIG. 6 is a circuit diagram of a variable delay circuit of a first embodiment;

FIG. 7A is a circuit diagram of a switch gate;

FIG. 7B is a truth table illustrating the operation of the switch gate;

FIG. 8A and FIG. 8B are diagrams explaining the operation of the switch gate, wherein FIG. 8A illustrates the operating state when CTi to be applied to ena is 0 and M=1, and FIG. 8B illustrates the operating state when CTi to be applied to ena is 1 and M2=1;

FIG. 9 is a diagram illustrating delays at the gates that are passed through when the return position is changed stepwise in the variable delay circuit of the first embodiment;

FIG. 10A and FIG. 10B are diagrams illustrating the delay times HM, LM when the switch gate in FIG. 7A is manufactured by a typical process, wherein FIG. 10A illustrates the case where the switch gate is manufactured by the process with a gate length of 90 nm and FIG. 10B illustrates the case where the switch gate is manufactured by the process with a gate length of 130 nm;

FIG. 11 is a circuit diagram of a variable delay circuit of a second embodiment;

FIG. 12A is a circuit diagram of the balance NAND gate;

FIG. 12B is a circuit diagram of an inverter;

FIG. 13A is a diagram illustrating a truth table indicating the operation of the balance NAND gate;

FIGS. 13B and 13C are diagrams explaining the operation of the circuit illustrated in FIG. 12A;

FIG. 14 is a diagram illustrating delays at the gates that are passed through when the return position is changed stepwise in the variable delay circuit of the second embodiment;

FIG. 15A and FIG. 15B are diagrams illustrating the delay times HM, LM when the balance NAND gate in FIG. 11 is manufactured by a typical process, wherein FIG. 15A illustrates the case where the balance NAND gate is manufactured by the process with a gate length of 90 nm and FIG. 15B illustrates the case where the balance NAND gate is manufactured by the process with a gate length of 130 nm;

FIG. 16A is a circuit diagram of a variable delay circuit of a third embodiment;

FIG. 16B is a circuit diagram of an adjustment NAND gate;

FIG. 17A is a diagram illustrating a truth table indicating the operation of the adjustment NAND gate;

FIG. 17B and FIG. 17C are diagrams explaining the operation of the adjustment NAND gate of the third embodiment;

FIG. 18A is a diagram of a general variable delay circuit in which the gate of the delay unit is formed by a two-input NOR gate;

FIG. 18B illustrates the two-input NOR gate;

FIG. 19A and FIG. 19B are diagrams illustrating the delay times HF, LF, HS, LS when the two-input NOR gate of CMOS type in FIG. 18B is manufactured by a typical process, wherein FIG. 19A illustrates the case where the two-input NOR gate is manufactured by the process with a gate length of 90 nm and FIG. 19B illustrates the case where the two-input NOR gate is manufactured by the process with a gate length of 130 nm;

FIG. 20A is a circuit diagram of a variable delay circuit of a fourth embodiment;

FIG. 20B is a circuit diagram of the switch NOR gate;

FIG. 21 is a diagram illustrating first and second control data in the fourth embodiment;

FIG. 22A is a diagram illustrating a truth table illustrating the operation of the switch NOR gate;

FIG. 22B and FIG. 22C are diagrams explaining the operation of the switch NOR gate;

FIG. 23A and FIG. 23B are diagrams illustrating the delay times HM, LM when the switch NOR gate in FIG. 20B is manufactured by a typical process, wherein FIG. 23A illustrates the case where the switch NOR gate is manufactured by the process with a gate length of 90 nm and FIG. 23B illustrates the case where the switch NOR gate is manufactured by the process with a gate length of 130 nm;

FIG. 24A is a circuit diagram of the balance NOR gate;

FIG. 24B and FIG. 24C are circuit diagrams explaining the operation of the balance NOR gate;

FIG. 25A and FIG. 25B are diagrams illustrating the delay times HM, LM when the balance NOR gate in FIG. 24A is manufactured by a typical process, wherein FIG. 25A illustrates the case where the balance NOR gate is manufactured by the process with a gate length of 90 nm and FIG. 25B illustrates the case where the balance NOR gate is manufactured by the process with a gate length of 130 nm.

### DESCRIPTION OF EMBODIMENTS

Before the embodiments are explained, a conventional variable delay circuit will be explained.

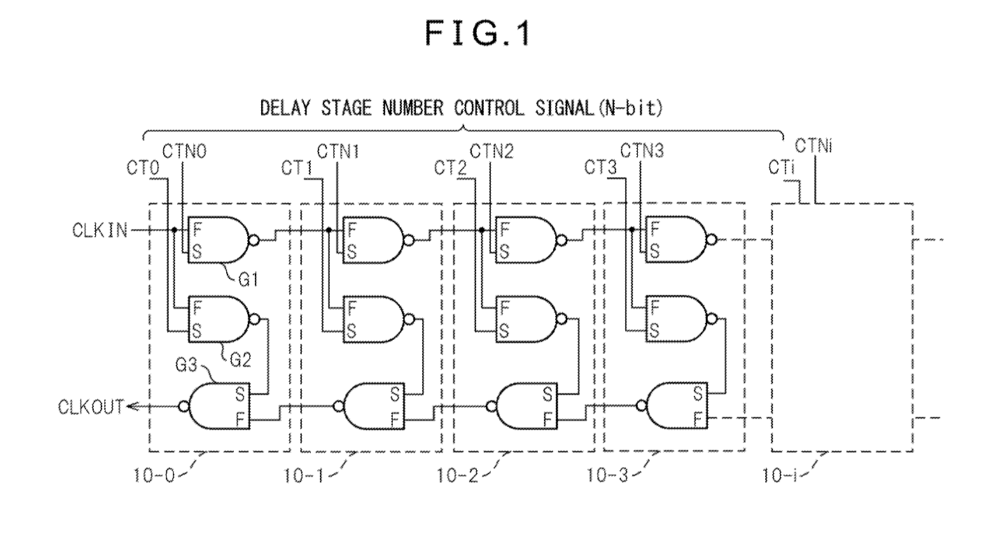

FIG. 1 is a circuit diagram illustrating a conventional variable delay circuit in which a plurality of delay units 10-0, 10-1, 10-2, 10-3, . . . , 10-i, . . . , each having three two-input NAND gates is connected in series. Each delay unit is the same circuit and has a first NAND gate G1, a second NAND gate G2, and a third NAND gate G3. As will be described later, the two input terminals of the two-input NAND gate have different delay times from when the input signal changes until the output signal changes. Here, the faster input terminal is represented by “F” and the slower input terminal by “S”.

An input signal CLKIN of each stage is input to the input terminal F of the first NAND gate G1 and the input terminal F of the second NAND gate G2. To the input terminal S of the first NAND gate G1, first control data CTN0, CTN1, CTN2, CTN3, . . . , CTNi, . . . , is input. The output of the first NAND gate G1 forms the input signal of the subsequent stage. Consequently, the first NAND gates G1 of the plurality of the delay units are connected in series so that the output of the previous stage is input to the subsequent stage.

To the input terminal S of the second NAND gate G2, second control data CT0, CT1, CT2, CT3, . . . , CTi, . . . , is input. The output of the second NAND gate G2 is input to the input terminal S of the third NAND gate G3.

The input terminal F of the third NAND gate G3 receives the output of the third NAND gate G3 of the subsequent stage. Consequently, the third NAND gates G3 of the plurality of the delay units are connected in series. Generally, the serial connection is represented by that the output of the previous stage is input to the subsequent stage, however, representation is such that the third NAND gates G3 are connected in series so that the output of the subsequent stage is input to the previous stage in order to maintain the consistency with the connection of the plurality of the delay units. The output of the third NAND gate G3 in the first stage is an output signal CLKOUT.

In the variable delay circuit in FIG. 1, it is possible to adjust the delay amount by specifying the position of the return path through which the input signal CLKIN transmitted through the first NAND gate G1 enters the third NAND gate G3 through the second NAND gate G2 with the first and second control data.

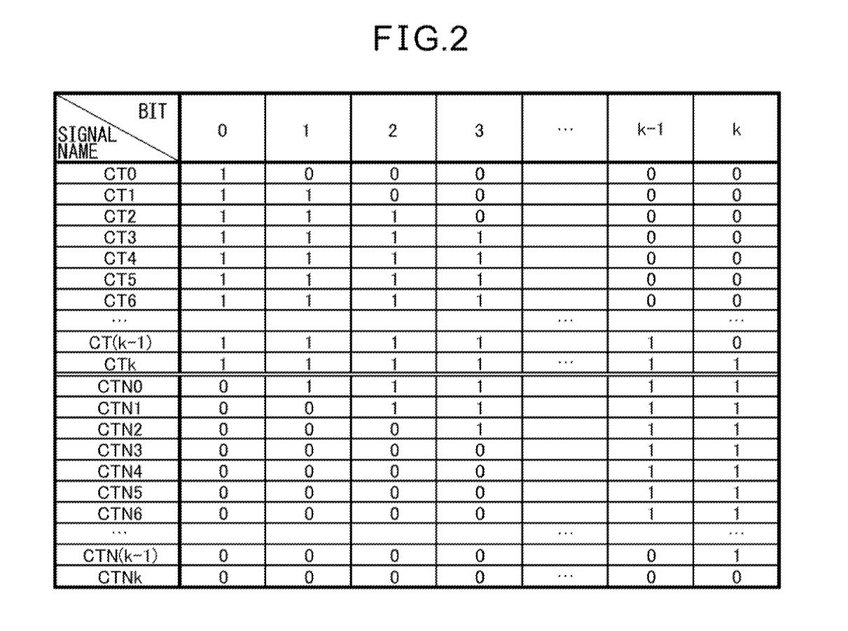

FIG. 2 is a diagram illustrating the first and second control data. In FIG. 2, bits indicate the position of the delay unit in the return path and bit=0 indicates a case where the return path is set in the delay unit 10-0 and bit=k indicates a case where the return path is set in the delay unit 10-k. Logic value “1” corresponds to the high (H) level of a signal and logic value “0” to the low (L) level of the signal.

As illustrated in FIG. 2, when the return path is set in the delay unit 10-k (bit=k), CTi (i=0 to k−1)=0, CTk=1, CTNi=1 (i=0 to k−1), and CTNk=0 are set.

The operation of the variable delay circuit in FIG. 1 is widely known, and therefore, further explanation is omitted here.

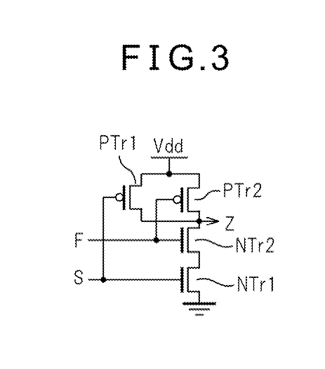

FIG. 3 is a circuit diagram illustrating an example of the two-input NAND gate. As illustrated in FIG. 3, the two-input NAND gate has two P-channel transistors PTr1 and PTr2 and two N-channel transistors NTr1 and NTr2. PTr1 and PTr2 are connected in parallel between a high-potential side power source Vdd and an output (node) Z. NTr1 and NTr2 are connected in series in this order between a low-potential side power source GND and the output Z. The input terminal S on one side is connected to the gates of PTr1 and NTr1 and the input terminal F on the other side is connected to the gates of PTr2 and NTr2. The NAND gate in FIG. 3 is widely known, and therefore, detailed explanation is omitted.

In the two-input NAND gate in FIG. 3, when the signal of the input terminal S is at the high (H) level, PTr1 is in the OFF state and NTr1 in the ON state. In this state, when the signal of the input terminal F turns to H, PTr2 turns off, NTr2 turns on, and the output turns to the low (L) level. Further, in this state, when the signal of the input terminal F turns to L, PTr2 turns on, NTr2 turns off, and the output turns to H. Consequently, the output changes according to the signal of the input terminal F. On the other hand, when the signal of the input terminal S is at the L level, PTr1 is in the ON state and NTr1 in the OFF state, and the output turns to H regardless of the signal of the input terminal F.

On the other hand, when the signal of the input terminal F is at H, PTr2 is in the off stage, and NTr2 in the ON state. In this state, when the signal of the input terminal S turns to H, PTr1 turns off, NTr1 turns on, and the output turns to L. Further, in this state when the signal of the input terminal S turns to L, PTr1 turns on, NTr1 turns off, and the output turns to H. Consequently, the output changes according to the signal of the input terminal S. On the other hand, when the signal of the input terminal F is at the L level, PTr2 is in the ON state, NTr2 in the OFF state, and the output turns to H regardless of the signal of the input terminal S.

The input signal CLKIN is transmitted in one of the states described above.

NTr1 the gate of which is connected to the input terminal S and NTr2 the gate of which is connected to the input terminal F are connected in series between GND and the output node. The distances of NTr1 and NTr2 from the output Z (and GND) are different, and therefore, an unavoidable delay error occurs for the input signals of the two input terminals F and S.

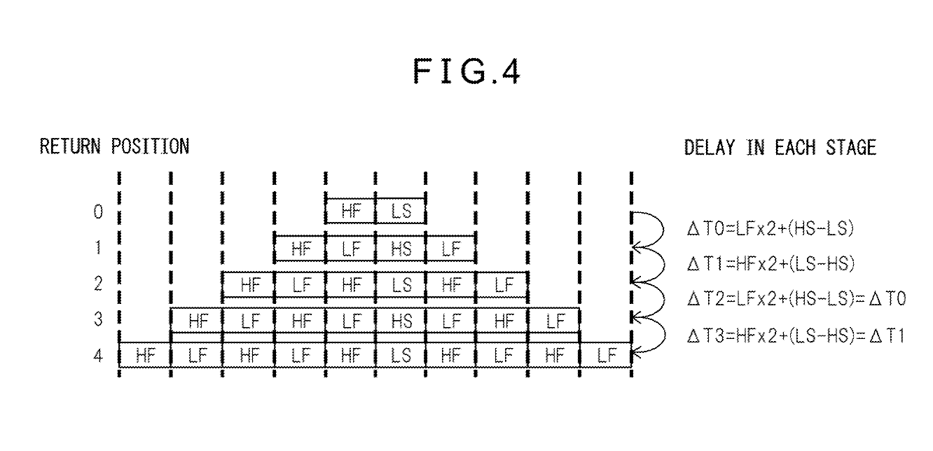

FIG. 4 is a diagram illustrating delays at the gates that are passed through when the return position is changed stepwise in the variable delay circuit in FIG. 1. As described above, in the two-input NAND gate, the delay time from when the input signal changes until the output signal changes differs depending on the input terminal and differs between the case where the input signal changes from L to H and the case where from H to L. It is assumed that the delay in the change edge of the input signal CLKIN from the low (L) level to the high (H) level is adjusted. When the input signal is inverted in the NAND gate and input to the next NAND gate, the delay in the change edge from H to L causes a problem. The delay when a signal from L to H is input to the input terminal F is represented as HF, the delay when a signal from L to H is input to the input terminal S as HS, the delay when a signal from H to L is input to the input terminal F as LF, and the delay when a signal from H to L is input to the input terminal S as LS.

When returned at bit 0, CLKIN is input to the input terminal F of G2 of the delay unit 10-0, inverted, and output and is input to the input terminal S of G3, inverted again, and output from the output terminal of G3 as CLKOUT. Consequently, the delay in this case is HF+LS.

When returned at bit 1, CLKIN is input to the input terminal F of G1 of the delay unit 10-0, inverted, and output and is input to the input terminal F of G2 of the delay unit 10-1, inverted, and output and is input to the input terminal S of G3, inverted, and output. Further, the output of G3 is input to the input terminal F of G3 of the delay unit 10-0, inverted, and output as CLKOUT. Consequently, the delay in this case is HF+LF+HS+LF. This also applies to the following similarly, and the delay when returned at bit 2 is HF+LF+HF+LS+HF+LS. The delay when returned at bit 3 is HF+LF+HF+LF+HS+LF+HF+LS. The delay when returned at bit 4 is HF+LF+HF+LF+HF+LS+HF+LF+HF+LS.

A delay difference ΔT0 between when returned at bit 0 and when at bit 1 is LF×2+(HS−LS). A delay difference ΔT1 between when returned at bit 1 and when at bit 2 is HF×2+(LS−HS). A delay difference ΔT2 between when returned at bit 2 and when at bit 3 is LF×2+(HS−LS)=ΔT0. A delay difference ΔT3 between when returned at bit 4 and when at bit 3 is HF×2+(LS−HS)=ΔT1. In this manner, in the variable delay circuit in FIG. 1, the delay time increases by ΔT0 when the stage changes from an odd-numbered stage to an even-numbered stage and the delay time increases by ΔT1 when the stage changes from an even-numbered stage to an odd-numbered stage.

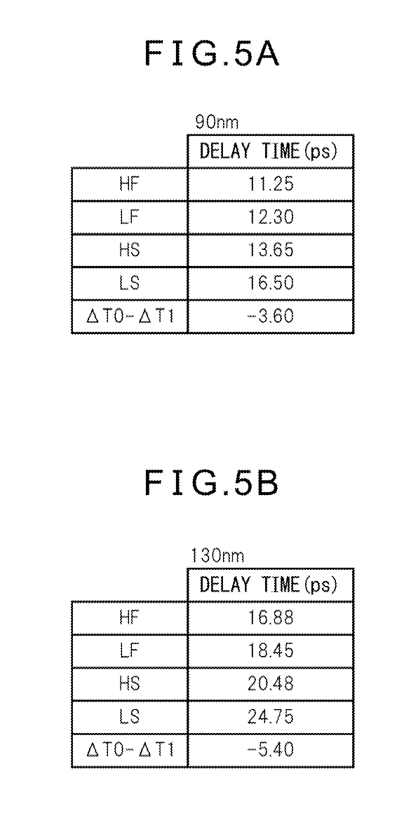

FIG. 5A and FIG. 5B are diagrams illustrating the delay times HF, LF, HS, LS when the two-input NAND gate of CMOS type in FIG. 3 is manufactured by a typical process, wherein FIG. 5A illustrates the case where the two-input NAND gate is manufactured by a process with a gate length of 90 nm and FIG. 5B illustrates the case where the two-input NAND gate is manufactured by a process with a gate length of 130 nm.

In the case illustrated in FIG. 5A, ΔT0=21.75 ps and ΔT1=25.35 ps, and therefore, their difference is ΔT0−ΔT1=−3.60 ps.

In the case illustrated in FIG. 5B, ΔT0=32.63 ps and ΔT1=38.03 ps, and therefore, their difference is ΔT0−ΔT1=−5.40 ps.

As explained above, in the variable delay circuit in FIG. 1, the amount of change in delay time ΔT0 when the stage changes from an odd-numbered stage to an even-numbered stage and the amount of change in delay time ΔT1 when the stage changes from an even-numbered stage to an odd-numbered stage are different, and therefore, the difference as described above is produced, causing an error in the variable delay circuit. In the variable delay circuit used in a signal input/output circuit that operates at high speed, such an error may not be ignored and reduction in the operating speed is caused by the error.

Embodiments are explained below.

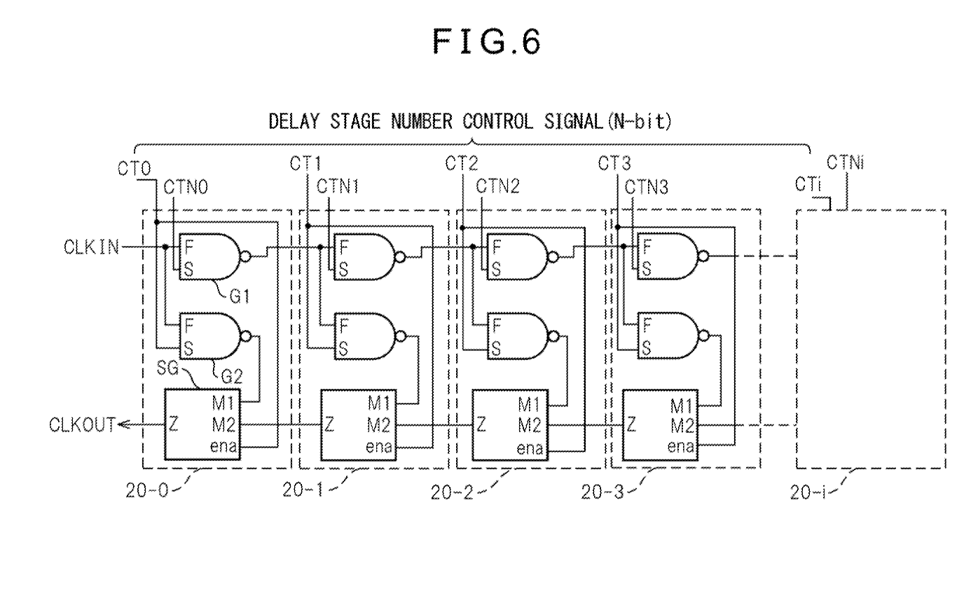

FIG. 6 illustrates a circuit diagram of a variable delay circuit of a first embodiment. The variable delay circuit of the first embodiment is a circuit diagram illustrating a variable delay circuit in which a plurality of delay units 20-0, 20-1, 20-2, 20-3, . . . , 20-i, . . . , is connected in series. Each delay unit is the same circuit and has the first NAND gate G1, the second NAND gate G2, and a switch gate SG. As obvious from comparison with FIG. 1, the variable delay circuit of the first embodiment differs in that the switch gate SG is provided in place of the third NAND gate G3 in the general variable delay circuit in FIG. 1 and other parts are the same. The switch gate SG has a first input terminal M1, a second input terminal M2, and a control terminal ena. The first input terminal M1 and the second input terminal M2 are connected in the same manner as the input terminals S and F of the two-input NAND gate in FIG. 1. Specifically, to the first input terminal M1, the output of the second NAND gate G2 is input. To the second input terminal M2, the output Z of the switch gate SG in the delay unit in the subsequent stage is input. To the control terminal ena, second control data CT0, CT1, CT2, CT3, . . . , CTNi, . . . , is input. The output Z of the switch gate SG of the first stage is the output signal CLKOUT.

In the variable delay circuit of the first embodiment in FIG. 6, it is possible to adjust the amount of delay by specifying the position of the return path where the input signal CLKIN transmitted via the first NAND gate G1 enters the switch gate SG through the second NAND gate G2 with the first control data CTN0, CTN1, CTN2, CTN3, . . . , CTNi, . . . , and the second control data CT0, CT1, CT2, CT3, . . . , CTNi, . . . . As the first control data and the second control data, the data illustrated in FIG. 2 may be used.

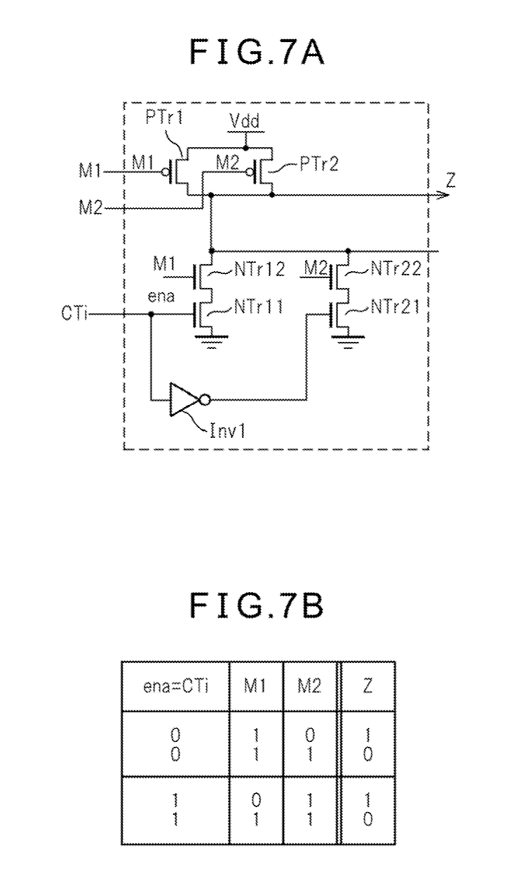

FIG. 7A is a circuit diagram of the switch gate SG. As illustrated in FIG. 7A, the switch gate SG has the two P-channel MOS transistors PTr1 and PTr2, four N-channel MOS transistors NTr11, NTr12, NTr21, and TNr22, and an inverter Inv1. PTr1 and PTr2 are connected in parallel between the high-potential side power source Vdd and the output Z and to the gate of PTr1, the signal of the first input terminal M1 is applied and to the gate of PTr2, the signal of the second input terminal M2 is applied. NTr11 and NTr12 are connected in series in this order between GND and the output Z and form a first row and to the gate of NTr11, the signal of the control terminal ena is applied and to the gate of NTr12, the signal of the first input terminal M1 is applied. To the control terminal ena, the second control data CTi is input. NTr21 and NTr22 are connected in series in this order between GND and the output Z and form a second row and to the gate of NTr21, the signal that is the signal of the control terminal ena inverted in Inv1 is applied and to the gate of NTr22, the signal of the second input terminal M2 is applied.

FIG. 7B is a truth table illustrating the operation of the switch gate SG. As illustrated in FIG. 7B, in the switch gate SG, when the second control data CTi to be applied to the control terminal ena is at L (0) and the signal of the first input terminal M1 is at H (1), according to the signal of the second input terminal M2, the output Z that is the inverted signal of M2 is obtained. When the second control data CTi to be applied to the control terminal ena is at H (1) and the signal of the second input terminal M2 is at H (1), according to the signal of the first input terminal M1, the output Z that is the inverted signal of M1 is obtained.

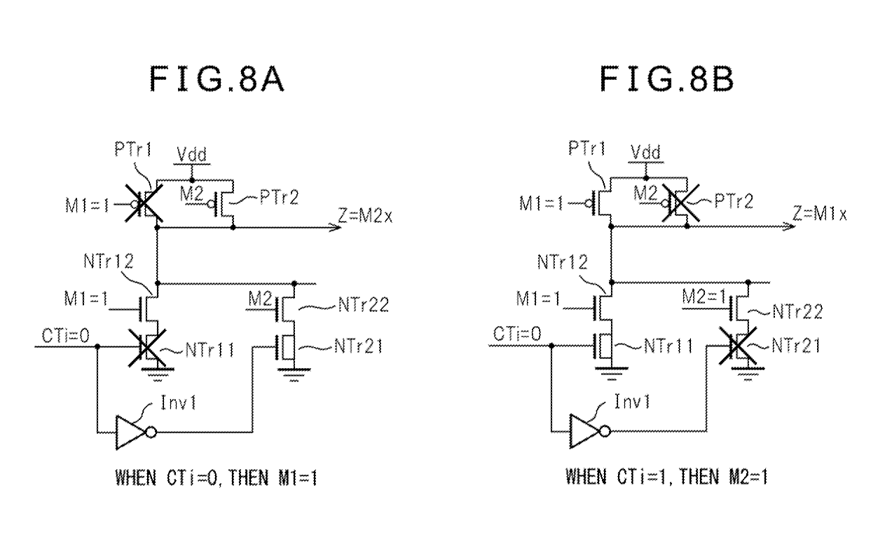

FIG. 8A and FIG. 8B are diagrams for explaining the operation of the switch gate SG, wherein FIG. 8A illustrates the operating state when CTi to be applied to ena is 0 and M=1 and FIG. 8B illustrates the operating state when CTi to be applied to ena is 1 and M2=1, respectively.

As illustrated in FIG. 8A, when CTi=0 and M1=1, PTr1 and NTr11 are in the OFF state and NTr12 and NTr21 enter the ON state. Because NTr11 is in the OFF state, the output Z is not affected even if NTr12 is in the ON state. Since NTr21 is in the ON state, NTr22 enters a state of being substantially connected to GND. Consequently, the switch gate SG enters a state where PTr2 and NTr22 are connected in series between Vdd and GND and the output Z is obtained from the connection node of PTr2 and NTr22. This state corresponds to the inverter circuit of the signal of the second input terminal M2 and the output Z turns to a signal M2x, which is the inverted signal of M2.

As illustrated in FIG. 8B, when CTi=1 and M2=1, PTr2 and NTr21 are in the OFF state and NTr11 and Tr22 enter the ON state. Because NTr21 is in the OFF state, the output Z is not affected even if NTr22 is in the ON state. Since NTr11 is in the ON state, NTr12 enters a state of being substantially connected to GND. Consequently, the switch gate SG enters a state where PTr1 and NTr12 are connected in series between Vdd and GND and the output Z is obtained from the connection node of PTr1 and NTr12. This state corresponds to the inverter circuit of the signal of the first input terminal M1 and the output Z turns to a signal M1x, which is the inverted signal of M1.

As obvious from comparison between FIG. 8A and FIG. 8B, the switch gate SG is a circuit in which the signal of the first input terminal M1 and the signal of the second input terminal M2 are symmetric about the output. In other words, the switch gate SG is a circuit in which the number of transistors from the first input terminal M1 to the output Z and the number of transistors from the second input terminal M2 to the output Z are the same.

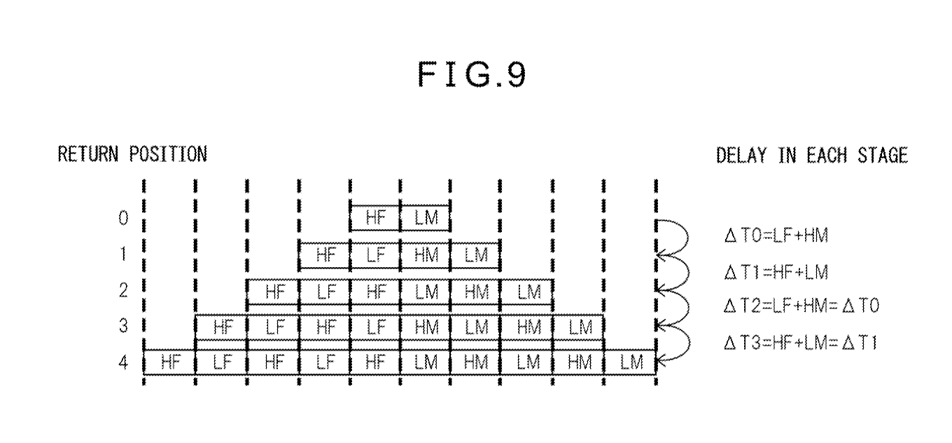

FIG. 9 is a diagram illustrating delays at the gates that are passed through when the return position is changed stepwise in the variable delay circuit of the first embodiment. HM represents the delay time from when the input signal of the input terminal M1 or the second input terminal M2 changes from L to H until the output Z changes from H to L. LM represents the delay time from when the input signal of the input terminal M1 or the second input terminal M2 changes from H to L until the output Z changes from L to H. As described above, the switch gate SG is a circuit in which the signal of the first input terminal M1 and the signal of the second input terminal M2 are symmetric about the output, and therefore, HM and LM are the same in the signal of the first input terminal M1 and the signal of the second input terminal M2.

As described above, it is assumed that the delay of the change edge of the input signal CLKIN from L to H is adjusted. When returned at bit 0, CLKIN is input to the input terminal F of G2 of the delay unit 20-0, inverted, and output and is input to the input terminal M1 of the switch gate SG, inverted again, and output as CLKOUT from the output terminal of SG. Consequently, the delay in this case is HF+LM.

When returned at bit 1, CLKIN is input to the input terminal F of G1 of the delay unit 20-0, inverted, and output and is input to the input terminal F of G2 of the delay unit 20-1, inverted, and output and is input to the input terminal M1 of the switch gate SG, inverted, and output. The output of the switch gate SG is further input to the input terminal M2 of SG of the delay unit 20-0, inverted, and output as CLKOUT. Consequently, the delay in this case is HF+LF+HM+LM. This also applies to the following similarly, and the delay when returned at bit 2 is HF+LF+HF+LM+HM+LM. The delay when returned at bit 3 is HF+LF+HF+LF+HM+LM+HM+LM. The delay when returned at bit 4 is HF+LF+HF+LF+HF+LM+HM+LM+HM+LM.

The delay difference ΔT0 between when returned at bit 0 and when at bit 1 is LF+HM. The delay difference ΔT1 between when returned at bit 1 and when at bit 2 is HF+LM. The delay difference ΔT2 between when returned at bit 2 and when at bit 3 is LF+HM=ΔT0. The delay difference ΔT3 between when returned at bit 4 and when at bit 3 is HF+LM=ΔT1.

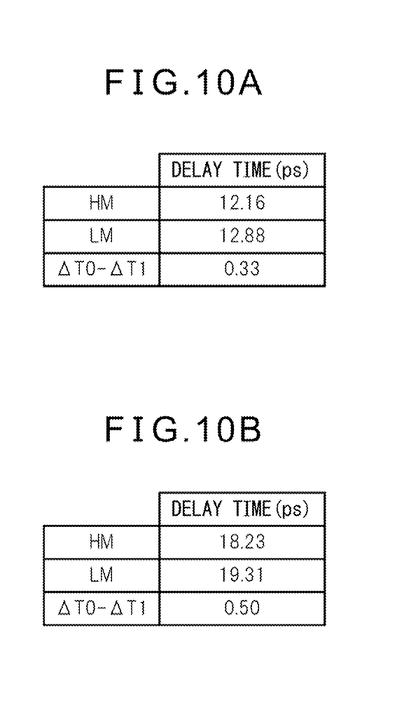

FIG. 10A and FIG. 10B are diagrams illustrating the delay times HM, LM when the switch gate SG in FIG. 7 is manufactured by a typical process, wherein FIG. 10A illustrates the case where the switch gate SG is manufactured by the process with a gate length of 90 nm and FIG. 10B illustrates the case where the switch gate SG is manufactured by the process with a gate length of 130 nm.

As illustrated in FIG. 10A, by the process with a gate length of 90 nm, HM=12.16 ps and LM=12.88 ps. As illustrated in FIG. 10B, by the process with a gate length of 130 nm, HM=18.23 ps and LM=19.31 ps.

Together with the delay time of the two-input NAND gate illustrated in FIG. 5A, in the case illustrated in FIG. 10A, ΔT0=24.46 ps and ΔT1=24.13 ps, and therefore, their difference is ΔT0−ΔT1=0.33 ps.

In the case illustrated in FIG. 10B, ΔT0=36.68 ps and ΔT1=36.19 ps, and therefore, their difference is ΔT0−ΔT1=0.49 ps.

In the variable delay circuit in FIG. 1, according to the value in FIG. 5A, ΔT0−ΔT1=−3.60 ps. Consequently, according to the value in FIG. 5B, in the variable delay circuit of the first embodiment, ΔT0−ΔT1=−5.40 ps and the difference ΔT0−ΔT1 is smaller compared to the circuit in FIG. 1.

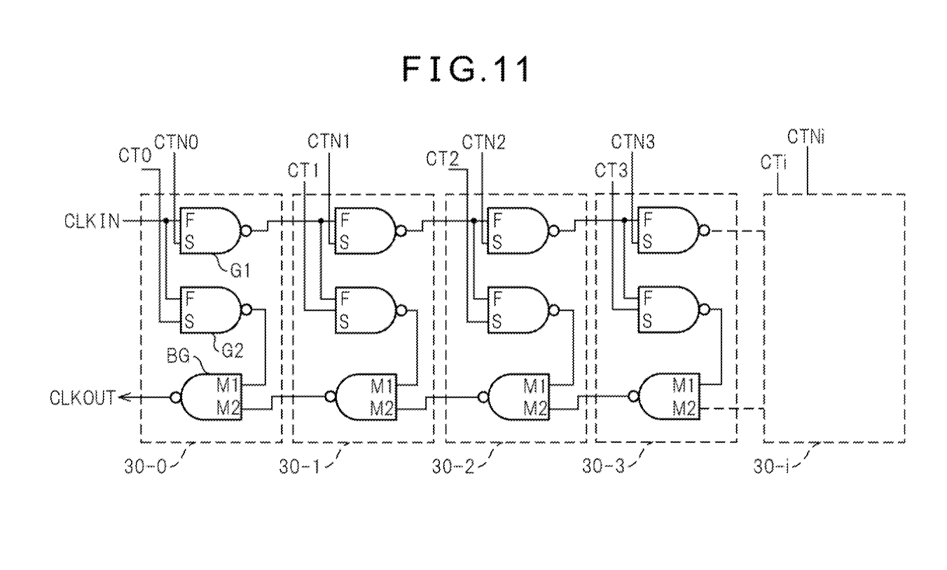

FIG. 11 illustrates a circuit diagram of a variable delay circuit of a second embodiment. The variable delay circuit of the second embodiment is a circuit diagram illustrating a variable delay circuit in which a plurality of delay units 30-0, 30-1, 30-2, 30-3, . . . , 30-i, . . . , is connected in series. Each delay unit is the same circuit and has the first NAND gate G1, the second NAND gate G2, and a balance NAND gate BG. As obvious from comparison with FIG. 1, the variable delay circuit of the second embodiment differs in that the balance NAND gate BG is provided in place of the third NAND gate G3 in the general variable delay circuit in FIG. 1 and other parts are the same. The balance NAND gate BG has the first input terminal M1 and the second input terminal M2. The first input terminal M1 and the second input terminal M2 are connected in the same manner as the input terminals S and F of the two-input NAND gate in FIG. 1. Specifically, to the first input terminal M1, the output of the second NAND gate G2 is input. To the second input terminal M2, the output Z of the balance NAND gate BG in the delay unit in the subsequent stage is input. The output Z of the balance NAND gate BG in the first stage is the output signal CLKOUT.

In the variable delay circuit of the second embodiment in FIG. 11, it is possible to adjust the amount of delay by specifying the position of the return path where the input signal CLKIN transmitted through the first NAND gate G1 enters the balance NAND gate BG through the second NAND gate G2 with the first control data CTN0, CTN1, CTN2, CTN3, . . . , CTNi, . . . , and the second control data CT0, CT1, CT2, CT3, . . . , CTi, . . . . As the first control data and the second control data, the data illustrated in FIG. 2 may be used.

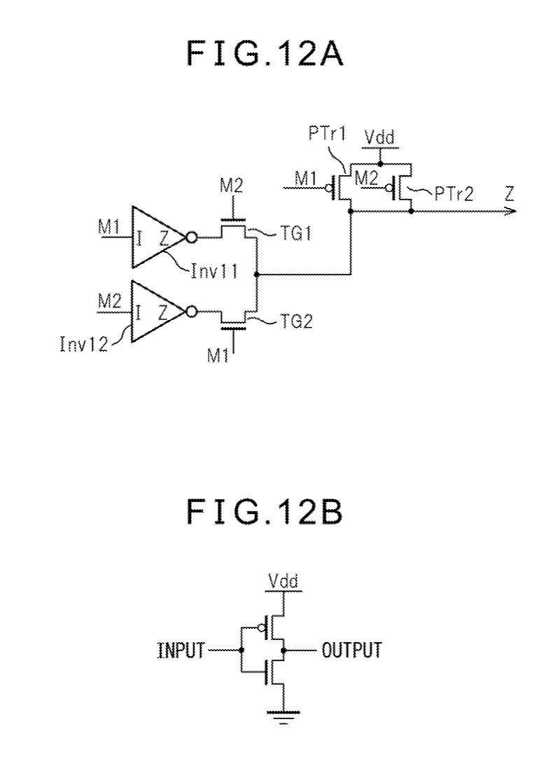

FIG. 12A and FIG. 12B are circuit diagrams of the balance NAND gate BG. As illustrated in FIG. 12A, the balance NAND gate BG has the two P-channel MOS transistors PTr1 and PTr2, two transfer gates TG1 and TG2, and two inverters Inv11 and Inv12. Inv11 and Inv12 have the circuit configuration illustrated in FIG. 12B.

PTr1 and PTr2 are connected in parallel between the high-potential side power source Vdd and the output Z and to the gate of PTr1, the signal of the first input terminal M1 is applied and to the gate of PTr2, the signal of the second input terminal M2 is applied. Inv11 receives the signal of the first input terminal M1 and outputs the inverted signal. Inv12 receives the signal of the second input terminal M2 and outputs the inverted signal. TG1 is connected between the output Z and the output of Inv11 and to the gate, the signal of the second input terminal M2 is applied. TG2 is connected between the output Z and the output of Inv12 and to the gate, the signal of the first input terminal M2 is applied. Consequently, when the signal of the second input terminal M2 is at H, the signal of the first input terminal M1 is inverted and output to the output Z and when the signal of the first input terminal M1 is at H, the signal of the second input terminal M2 is inverted and output to the output Z.

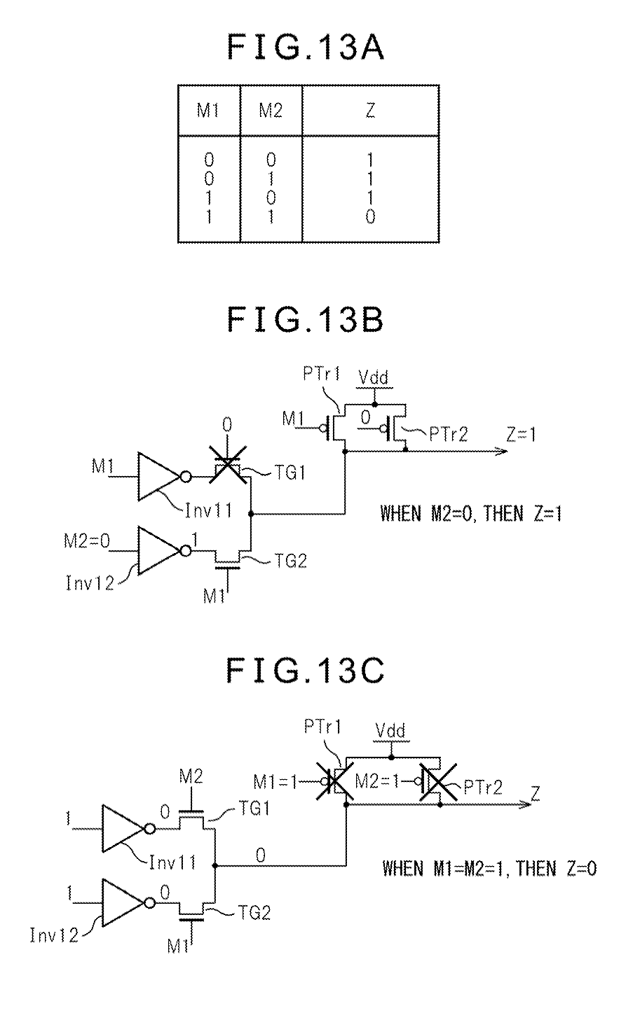

FIG. 13A to FIG. 13C are a truth table indicating the operation of the balance NAND gate BG and diagrams for explaining the operation thereof.

As illustrated in FIG. 13A, in the balance NAND gate BG, when both the signal of the first input terminal M1 and the signal of the second input terminal M2 are at H, the output Z turns to L and in other cases, the output Z turns to H. In other words, the balance NAND gate BG operates as a two-input NAND gate.

When the signal of the second input terminal M2 is at L (0), in the balance NAND gate BG, as illustrated in FIG. 13B, TG1 is in the OFF state and the output of Inv11 does not affect the output Z. At this time, PTr2 is in the ON state and the output Z turns to H (1). The output of Inv12 is at H (1). When the signal of the first input terminal M1 is at L (0), TG2 is in the OFF state and does not affect the output Z, and when the signal of the first input terminal M1 is at L (0), TG2 is in the ON state and the output of Inv12 at H is transmitted to the output Z, however, not contradictory to the above-mentioned output. When the signal of the first input terminal M1 is at L (0), PTr1 turns on, however, this is also not contradictory to the above-mentioned output.

FIG. 13B illustrates a case where the signal of the second input terminal M2 is at L (0), however, this also applies to the case where the signal of the first input terminal M1 is at L (0).

When both the signal of the first input terminal M1 and the signal of the second input terminal M2 are at H (1), as illustrated in FIG. 13C, PTr1 and PTr2 turn off, TG1 and TG2 turn on, the outputs of Inv11 and Inv12 at L (0) are transmitted to the output Z, and the output Z turns to L (0).

As described above, the balance NAND gate BG is a circuit in which the signal of the first input terminal M1 and the signal of the second input terminal M2 are symmetric about the output. In other words, the balance NAND gate BG is a circuit in which the number of transistors from the first input terminal M1 to the output Z and the number of transistors from the second input terminal M2 to the output Z are the same.

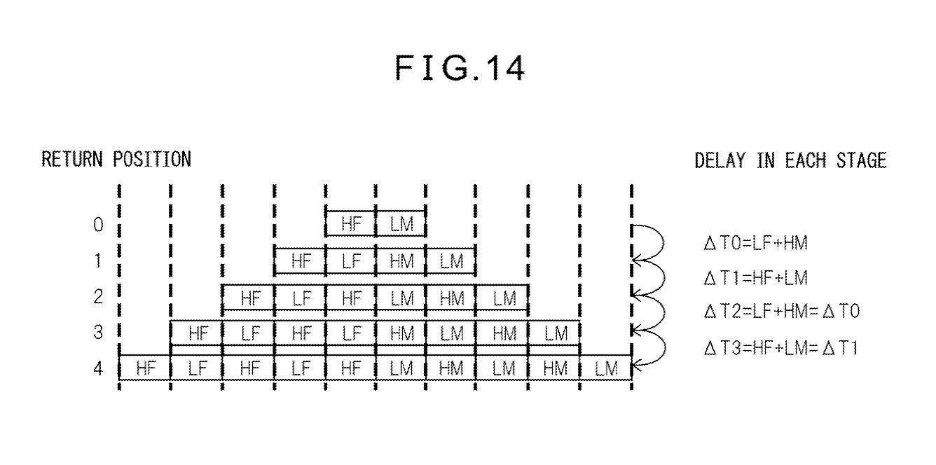

FIG. 14 is a diagram illustrating delays at the gates that are passed through when the return position is changed stepwise in the variable delay circuit of the second embodiment. HM represents the delay time from when the input signal of the input terminal M1 or the second input terminal M2 changes from L to H until the output Z changes from H to L. LM represents the delay time from when the input signal of the first input terminal M1 or the second input terminal M2 changes from H to L until the output Z changes from L to H. As described above, the balance NAND gate BG is a circuit in which the signal of the first input terminal M1 and the signal of the second input terminal M2 are symmetric about the output, and therefore, HM and LM are the same in the signal of the first input terminal M1 and the signal of the second input terminal M2.

As described previously, it is assumed that the delay of the change edge of the input signal CLKIN from L to H is adjusted. When returned at bit 0, CLKIN is input to the input terminal F of G2 of the delay unit 30-0, inverted, and output and is input to the input terminal M1 of the balance NAND gate BG, inverted again, and output as CLKOUT from the output terminal of BG. Consequently, the delay in this case is HF+LM.

When returned at bit 1, CLKIN is input to the input terminal F of G1 of the delay unit 30-0, inverted, and output and is input to the input terminal F of G2 of the delay unit 30-1, inverted, and output and is input to the input terminal M1 of the balance NAND gate BG, inverted, and output. Further, CLKIN is input to the input terminal M2 of BG of the delay unit 30-0, inverted, and output as CLKOUT. Consequently, the delay in this case is HF+LF+HM+LM. This also applies to the following similarly, and the delay when returned at bit 2 is HF+LF+HF+LM+HM+LM. The delay when returned at bit 3 is HF+LF+HF+LF+HM+LM+HM+LM. The delay when returned at bit 4 is HF+LF+HF+LF+HF+LM+HM+LM+HM+LM.

The delay difference ΔT0 between when returned at bit 0 and when at bit 1 is LF+HM. The delay difference ΔT1 between when returned at bit 1 and when at bit 2 is HF+LM. The delay difference ΔT2 between when returned at bit 2 and when at bit 3 is LF+HM=ΔT0. The delay difference ΔT3 between when returned at bit 4 and when at bit 3 is HF+LM=ΔT1.

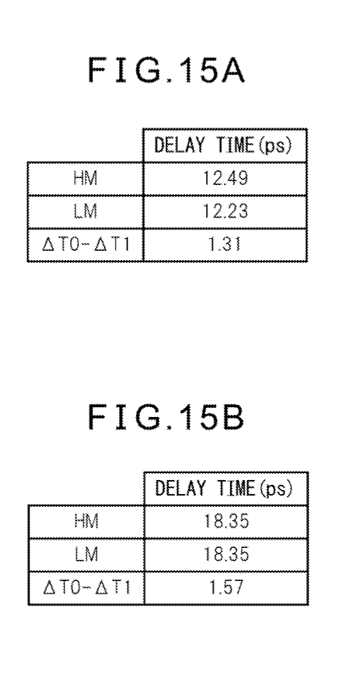

FIG. 15A and FIG. 15B are diagrams illustrating the delay times HM, LM when the balance NAND gate BG in FIG. 11 is manufactured by a typical process, wherein FIG. 15A illustrates the case where the balance NAND gate BG is manufactured by the process with a gate length of 90 nm and FIG. 15B illustrates the case where the balance NAND gate BG is manufactured by the process with a gate length of 130 nm.

As illustrated in FIG. 15A, by the process with a gate length of 90 nm, HM=12.49 ps and LM=12.23 ps. As illustrated in FIG. 15B, by the process with a gate length of 130 nm, HM=18.35 ps and LM=18.35 ps.

Together with the delay time of the two-input NAND gate illustrated in FIG. 5A, in the case illustrated in FIG. 15A, ΔT0=24.79 ps and ΔT1=23.48 ps, and therefore, their difference is ΔT0−ΔT1=1.31 ps.

In the case illustrated in FIG. 15B, ΔT0=36.80 ps and ΔT1=35.23 ps, and therefore, their difference is ΔT0−ΔT1=1.57 ps.

As described previously, in the variable delay circuit of FIG. 1, ΔT0−ΔT1 is 3.60 ps by the process with a gate length of 90 nm and −5.40 ps by the process with a gate length of 130 nm, and in the variable delay circuit of the second embodiment, the difference ΔT0−ΔT1 becomes smaller.

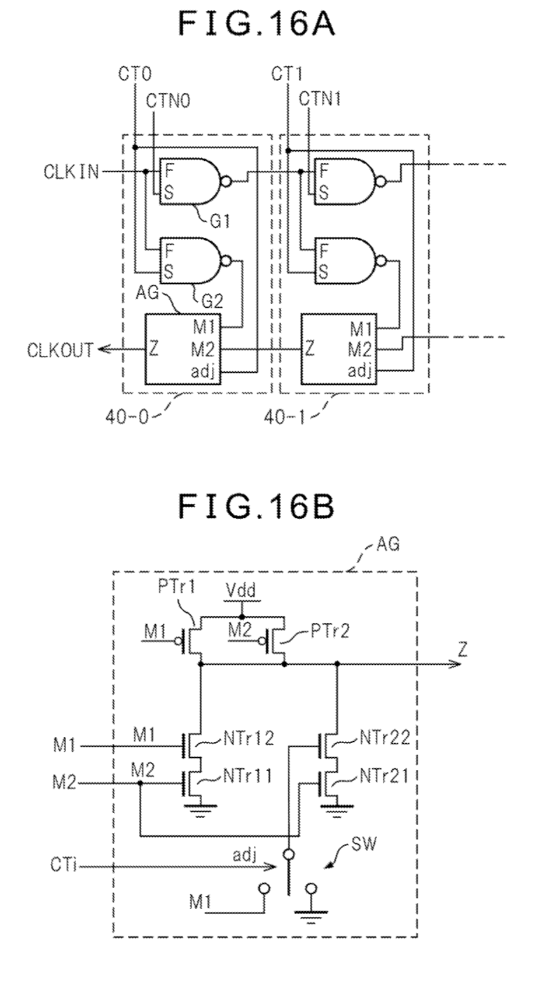

FIG. 16A and FIG. 16B illustrate circuit diagrams of a variable delay circuit of a third embodiment, wherein FIG. 16A illustrates a variable delay circuit and FIG. 16B is a circuit diagram of an adjustment NAND gate. The variable delay circuit of the third embodiment is a circuit diagram illustrating a variable delay circuit in which a plurality of delay units 40-0, 40-1, . . . , is connected in series. Each delay unit is the same circuit and has the first NAND gate G1, the second NAND gate G2, and an adjustment NAND gate AG. As obvious from comparison with FIG. 1, the variable delay circuit of the third embodiment differs in that the adjustment NAND gate AG is provided in place of the third NAND gate G3 in the general variable delay circuit in FIG. 1 and other parts are the same. The adjustment NAND gate AG has the first input terminal M1, the second input terminal M2, and an adjustment terminal adj. The first input terminal M1 and the second input terminal M2 are connected in the same manner as the input terminals S and F of the two-input NAND gate in FIG. 1. Specifically, to the first input terminal M1, the output of the second NAND gate G2 is input. To the second input terminal M2, the output Z of the adjustment NAND gate AG in the delay unit in the subsequent stage is input. To the adjustment terminal adj, the second data CT0, CT1, CT2, CT3, . . . , CTi, . . . , is input. The output Z of the adjustment NAND gate AG in the first stage is the output signal CLKOUT.

In the variable delay circuit of the third embodiment in FIG. 16A, it is possible to adjust the amount of delay by specifying the position of the return path where the input signal CLKIN transmitted through the first NAND gate G1 enters the adjustment NAND gate AG through the second NAND gate G2 with the first control data CTN0, CTN1, . . . , and the second control data CT0, CT1, . . . . As the first control data and the second control data, the data illustrated in FIG. 2 may be used.

As illustrated in FIG. 16A, the adjustment NAND gate AG has the two P-channel MOS transistors PTr1 and PTr2, the four N-channel MOS transistors NTr11, NTr12, NTr21, and TNr22, and a switch SW. PTr1 and PTr2 are connected in parallel between the high-potential side power source Vdd and the output Z and to the gate of PTr1, the signal of the first input terminal M1 is applied and to the gate of PTr2, the signal of the second input terminal M2 is applied. NTr11 and NTr12 are connected in series in this order between GND and the output Z and forms a first row and to the gate of NTr11, the signal of the second input terminal M2 is applied and to the gate of NTr12, the signal of the first input terminal M1 is applied. NTr21 and NTr22 are connected in series in this order between GND and the output Z and forms a second row and to the gate of NTr21, the signal of the second input terminal M2 is applied and to the gate of NTr22, the signal selected by the switch SW is applied. The switch SW selects one of the signal of the first input terminal M1 and GND according to the second control data CTi to be applied to the adjustment terminal adj.

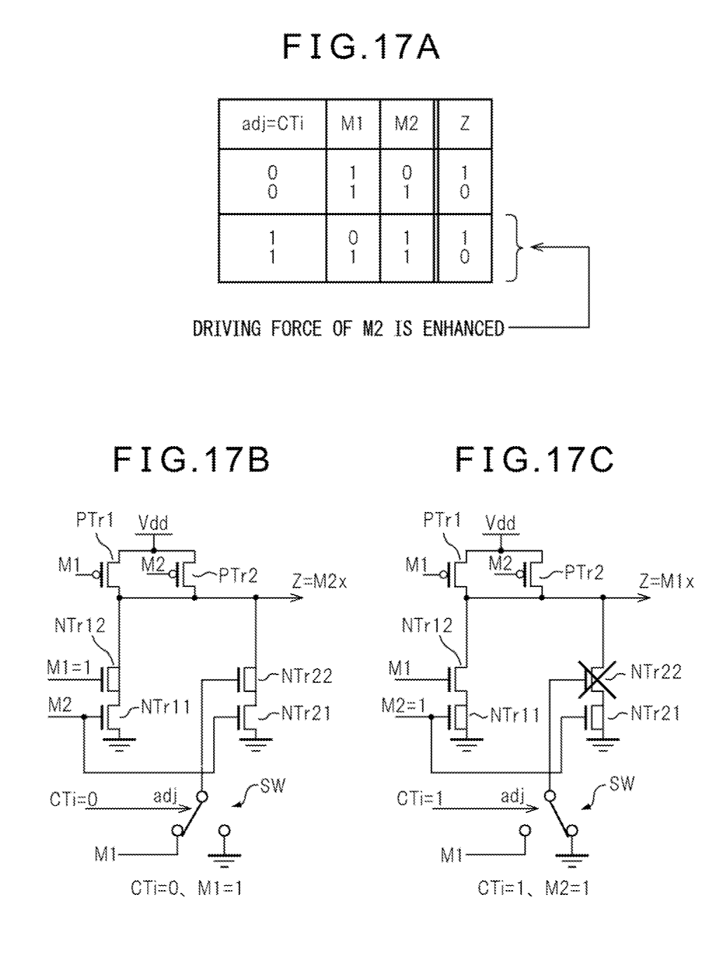

FIG. 17A to FIG. 17C are a truth table indicating the operation of the adjustment NAND gate AG and diagrams for explaining the operation thereof, wherein FIG. 17A illustrates a truth table, FIG. 17B illustrates an operating state when CTi to be applied to adj is 0, and FIG. 17C illustrates an operating state when CTi to be applied to adj is 1, respectively.

As illustrated in FIG. 17A, the adjustment NAND gate AG functions as a two-input NAND gate the inputs of which are the signal of the first input terminal M1 and the signal of the second input terminal M2 regardless of the second control data CTi to be applied to the adjustment terminal adj. Consequently, when both the signal of the first input terminal M1 and the signal of the second input terminal M2 are at H (1), the output Z turns to L (0) and in other cases, the output Z turns to H (1).

In the adjustment NAND gate AG, the driving force of the output Z becomes large when the second control data CTi to be applied to the adjustment terminal adj is at L (0) and smaller when CTi is at H (1).

When CTi=0, the output of G2 turns to H, and therefore, the signal of M1 is fixed to H (1). In other words, the adjustment NAND gate AG needs to operate as an inverter of the signal of M2. In this case, as illustrated in FIG. 17B, CTi=0 and M1=1 and SW selects the signal of the first input terminal M1. Due to this, a state is brought about where PTr1 turns off, NTr12 and NTr22 turn on, PTr2 is connected between Vdd and the output Z, and NTr11 and NTr21 are connected between the output Z and GND via NTr12 or NTr22, respectively. To the gates of PTr2, NTr11, and NTr21, the signal of M2 is applied, and therefore, the adjustment NAND gate AG operates as an inverter of the signal of M2 and the output Z turns to the signal M2x, which is the inverted signal of M2.

When CTi=1, the output of G2 changes according to CLKIN and the output of the adjustment NAND gate AG of the delay unit 40-i+1 turns to H, and therefore, the signal of M2 is fixed to H (1). In other words, the adjustment NAND gate AG needs to operate as an inverter of the signal of M1. In this case, as illustrated in FIG. 17C, CTi=1 and M2=1 and SW selects GND. Due to this, PTr2 turns off, NTr11 and NTr21 turn on, and NTr22 turns off. Since NTr22 turns off, NTr21 does not affect the output Z and a state is brought about where PTr1 is connected between Vdd and the output Z and NTr12 is connected between the output Z and GND via NTr11. To the gates of PTr1 and NTr12, the signal of M1 is applied, and therefore, the adjustment NAND gate AG operates as an inverter of the signal of M1 and the output Z turns to the signal M1x, which is the inverted signal of M1.

As explained with reference to FIG. 3, when the signals of M2 and M1 are applied to NTr11 and NTr12, respectively, connected in series between the output Z and GND, the unavoidable delay error for the signal of M2 and the signal of M1 occurs, that is, the change of the output Z for the signal of M2 is delayed compared to the change of the output Z for the signal of M1.

In contrast to this, in the third embodiment, as illustrated in FIG. 17B, when the adjustment NAND gate AG operates as an inverter of the signal of M2, a state is brought about where NTr11 and NTr21 are connected in parallel and the driving force is the sum of the driving force of NTr11 and the driving force of NTr12. Since the driving force becomes larger, the change of the output Z for the signal of M2 is advanced compared to the case where only NTr11 is provided.

Further, as illustrated in FIG. 17C, when the adjustment NAND gate AG operates as an inverter of the signal of M1, a state is brought about where NTr12 is connected between GND and the output Z and the driving force is only the driving force of NTr12. However, as explained with reference to the figure, the change of the output Z for the signal of M1 is originally more rapid than the change of the output Z for the signal of M2. As a result, in the third embodiment, it is possible to set the change of the output Z for the signal of M1 and the change of the output Z for the signal of M2 to substantially the same level.

When the variable delay circuit of the third embodiment is manufactured by the process with a gate length of 90 nm, all the gate widths of NTr11 to NTr22 are set to, for example, 0.45 μm and when manufactured by the process with a gate length of 130 nm, all the gate widths of NTr11 to NTr22 are set to, for example, 0.65 μm.

The example explained above is the variable delay circuit in which the gate of the delay unit is formed by the two-input NAND gate or a gate that operates in the same manner. In contrast to this, a variable delay circuit is known, in which the gate of the delay unit is formed by a two-input NOR gate.

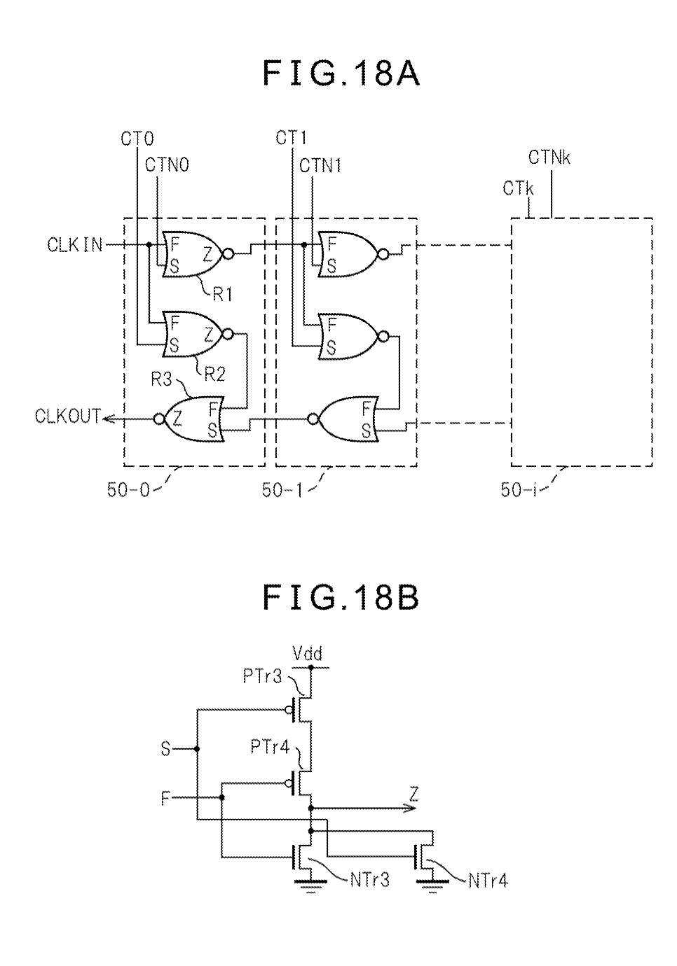

FIG. 18A is a diagram of a general variable delay circuit in which the gate of the delay unit is formed by a two-input NOR gate.

As illustrated in FIG. 18A, in the variable delay circuit, a plurality of delay units 50-0, 50-1, . . . , 50-i, . . . , each having three two-input NOR gates is connected in series. Each delay unit is the same circuit and has a first NOR gate R1, a second NOR gate R2, and a third NOR gate R3. As will be described later, the two input terminals of the two-input NOR gate have different delay times from when the input signal changes until the output signal changes. The faster input terminal is represented by “F” and the slower input terminal by “S”.

The input signal CLKIN of each stage is input to the input terminal F of the first NOR gate R1 and the input terminal F of the second NOR gate R2. To the input terminal S of the first NOR gate R1, the first control data CTN0, CTN1, . . . , CTNi, . . . , is input. The output of the first NOR gate R1 forms the input signal in the subsequent stage. Consequently, the first NOR gates R1 of the plurality of the delay units are connected in series so that the output of the previous stage is input to the subsequent stage.

To the input terminal S of the second NOR gate R2, the second control data CT0, CT1, . . . , CTi, . . . , is input. The output of the second NOR gate R2 is input to the input terminal F of the third NOR gate R3.

The input terminal S of the third NOR gate R3 receives the output of the third NOR gate R3 in the subsequent stage. Consequently, the third NOR gates R3 of the plurality of the delay units are connected in series. Representation is also such that the third NOR gates R3 are connected in series so that the output of the subsequent stage is input to the previous stage in order to maintain the consistency with the connection of the plurality of the delay units. The output of the third NOR gate R3 in the first stage is the output signal CLKOUT.

In the variable delay circuit in FIG. 18A, it is possible to adjust the amount of delay by specifying the position of the return path where the input signal CLKIN transmitted through the first NOR gate R1 enters the third NOR gate G3 through the second NOR gate R2 with the first and second control data.

The operation of the variable delay circuit in FIG. 18A is widely known, and therefore, more explanation is omitted.

FIG. 18B illustrates the two-input NOR gate.

As illustrated in FIG. 18B, the two-input NOR gate has two P-channel transistors PTr3 and PTr4 and two N-channel transistors NTr3 and NTr4. PTr3 and PTr4 are connected in series in this order between the high-potential side power source Vdd and the output node Z. NTr3 and NTr4 are connected in parallel between the low-potential side power source GND and the output node Z. The input terminal S on one side is connected to the gates of PTr3 and NTr3 and the input terminal F on the other side is connected to the gates of PTr4 and NTr4. The NOR gate in FIG. 18B is widely known, and therefore, detailed explanation is omitted.

In the two-input NOR gate in FIG. 18B, when the signal of the input terminal S is at the high (H) level, PTr3 is in the OFF state and NTr3 in the ON state, and the output turns to L regardless of the signal of the input terminal F. On the other hand, when the signal of the input terminal S is at the L level, PTr3 enters the ON state and NTr3 the OFF state. In this state, when the signal of the input terminal F turns to H, PTr4 turns off, NTr4 turns on, and the output turns to L. Further, in this state, when the signal of the input terminal F turns to L, PTr4 turns on, NTr4 turns off, and the output turns to H. Consequently, the two-input NOR gate operates as an inverter the output of which changes according to the signal of the input terminal F.

On the other hand, when the signal of the input terminal F is at H, PTr4 is in the OFF state and NTr4 in the ON state, and the output turns to L regardless of the signal of the input terminal S. On the other hand, when the signal of the input terminal F is at L, PTr4 enters the ON state and NTr4 the OFF state. In this state, when the signal of the input terminal S turns to H, PTr3 turns off, NTr3 turns on, and the output turns to L. Further, in this state, when the signal of the input terminal S turns to L, PTr3 turns on, NTr3 turns off, and the output turns to H. Consequently, the two-input NOR gate operates as an inverter the output of which changes according to the signal of the input terminal S.

The input signal CLKIN is transmitted in one of the states described above.

PTr3 the gate of which is connected to the input terminal S and PTr4 the gate of which is connected to the input terminal F are connected in series between Vdd and the output node. The distances of PTr3 and PTr4 from the output Z are different, and therefore, an unavoidable delay error occurs for the input signals of the two input terminals F and S.

In the two-input NOR gate illustrated in FIG. 18B, the delay time from when the input signal changes until the output signal changes differs between the input terminals and differs between the case where the input signal changes from L to H and the case where from H to L.

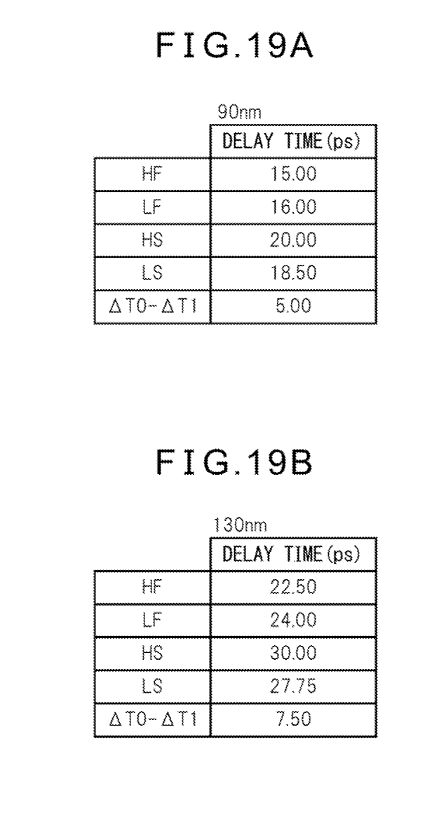

FIG. 19A and FIG. 19B are diagrams illustrating the delay times HF, LF, HS, LS when the two-input NOR gate of CMOS type in FIG. 18B is manufactured by a typical process, wherein FIG. 19A illustrates the case where the two-input NOR gate is manufactured by the process with a gate length of 90 nm and FIG. 19B illustrates the case where manufactured by the process with a gate length of 130 nm.

In the variable delay circuit in FIG. 18A, the difference ΔT0−ΔT1 between the increase in the delay time ΔT0 when the stage changes from an odd-numbered stage to an even-numbered stage and the increase in the delay time ΔT1 when the stage changes from an even-numbered stage to an odd-numbered stage is 5.00 ps in the case illustrated in FIG. 19A and 7.50 ps in the case illustrated in FIG. 19B.

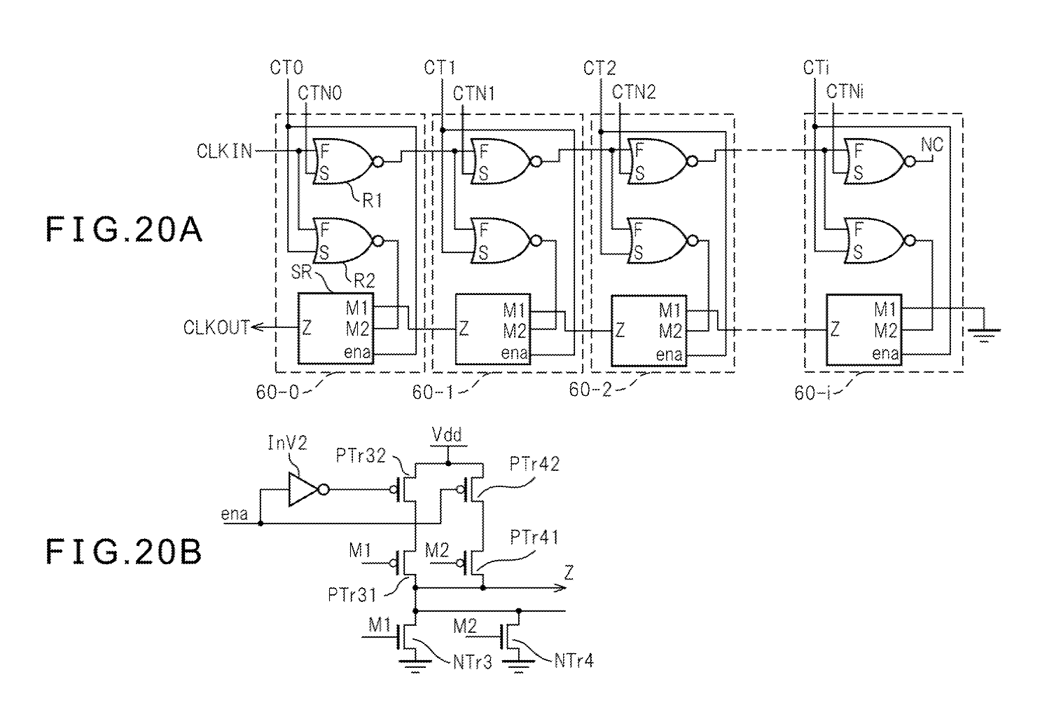

FIG. 20A is a circuit diagram of a variable delay circuit of a fourth embodiment.

The variable delay circuit of the fourth embodiment is a circuit diagram illustrating a variable delay circuit in which a plurality of delay units 60-0, 60-1, 60-2, . . . , 60-i, . . . , is connected in series. Each delay unit is the same circuit and has the first NOR gate R1, the second NOR gate R2, and a switch NOR gate SR. As obvious from comparison with FIG. 18A, the variable delay circuit of the fourth embodiment differs in that the switch NOR gate SR is provided in place of the third NOR gate R3 in the general variable delay circuit in FIG. 18A and other parts are the same. The switch NOR gate SR has the first input terminal M1, the second input terminal M2, and the control terminal ena. The first input terminal M1 and the second input terminal M2 are connected in the same manner as the input terminals S and F of the two-input NAND gate in FIG. 1. Specifically, to the first input terminal M1, the output Z of the switch NOR gate SR of the delay unit in the subsequent stage is input. To the second input terminal M2, the output of the second NAND gate G2 is input. To the control terminal ena, the second control data CT0, CT1, CT2, . . . , CTNi, . . . , is input. The output Z of the switch NOR gate SR in the first stage is the output signal CLKOUT.

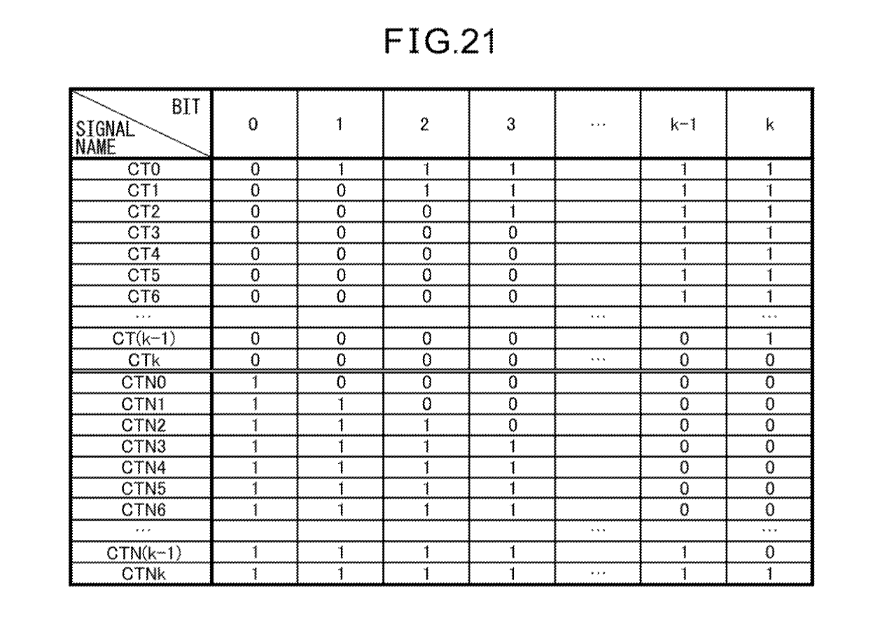

In the variable delay circuit of the fourth embodiment in FIG. 20A, it is possible to adjust the amount of delay by specifying the position of the return path where the input signal CLKIN transmitted through the first NOR gate R1 enters the switch NOR gate SR through the second NOR gate R2 with the first control data CTN0, CTN1, CTN2, . . . , CTNi, . . . , and the second control data CT0, CT1, CT2, . . . , CTi, . . . . As the first control data and the second control data, the data illustrated in FIG. 21 may be used.

FIG. 20B is a circuit diagram of the switch NOR gate SR.

As illustrated in FIG. 20B, the switch NOR gate SR has four P-channel MOS transistors PTr31, PTr32, PTr41, and PTr42, the two N-channel MOS transistors NTr3 and TNr4, and an inverter Inv2. NTr3 and NTr4 are connected in parallel between the low-potential side power source GND and the output Z and to the gate of NTr3, the signal of the first input terminal M1 is applied and to the gate of NTr4, the signal of the second input terminal M2 is applied. PTr31 and PTr32 are connected in series in this order between the output Z and the high-potential side power source Vdd and forms a first row, to the gate of PTr31, the signal of the first input terminal M1 is applied, and to the gate of PTr32, the signal of the control terminal ena inverted in Inv2 is applied. To the control terminal ena, the second control data CTi is input. PTr41 and PTr42 are connected in series in this order between the output Z and Vdd and forms a second row and to the gate of NTr41, the signal of the second input terminal M2 is applied and to the gate of PTr42, the signal of the control terminal ena is applied.

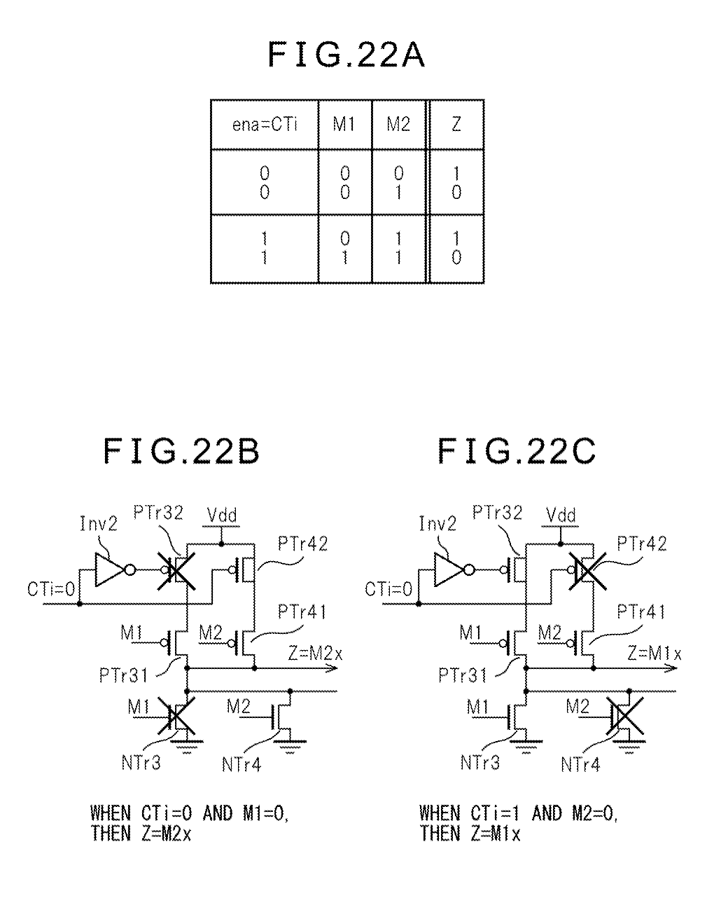

FIG. 22A to FIG. 22C are a truth table illustrating the operation of the switch NOR gate SR and diagrams for explaining the operation thereof.

As illustrated in FIG. 22A, in the switch NOR gate SR, when the second control data CTi to be applied to the control terminal ena is at L (0) and the signal of the first input terminal M1 is at L (0), the output Z, which is the inverted signal of M2, is obtained according to the signal of the second input terminal M2. When the second control data CTi to be applied to the control terminal ena is at H (1) and the signal of the second input terminal M2 is at L (0), the output Z, which is the inverted signal of M1, is obtained according to the signal of the first input terminal M1.

FIG. 22B illustrates an operating state when CTi to be applied to ena is 0 and M1=0 and FIG. 22C illustrates an operating state when CTi to be applied to ena is 1 and M2=0, respectively.

As illustrated in FIG. 22B, when CTi=0 and M1=0, PTr32 and NTr3 are in the OFF state and PTr31 and PTr42 enter the ON state. Since PTr32 is in the OFF state, the output Z is not affected even if PTr31 is in the ON state. Since PTr42 is in the ON state, PTr41 enters a state of being substantially connected to Vdd. Consequently, the switch NOR gate SR enters a state where PTr41 and NTr4 are connected in series between Vdd and GND and the output Z is obtained from the connection node of PTr41 and NTr4. This state corresponds to an inverter circuit of the signal of the second input terminal M2 and the output Z turns to the signal M2x, which is the inverted signal of M2.

As illustrated in FIG. 22C, when CTi=1 and M2=0, PTr42 and NTr4 are in the OFF state and PTr32 and PTr41 enter the ON state. Because PTr42 is in the OFF state, the output Z is not affected even if PTr41 is in the ON state. Because PTr32 is in the ON state, PTr31 enters a state of being substantially connected to Vdd. Consequently, the switch NOR gate SR enters a state where PTr3 and NTr3 are connected in series between Vdd and GND and the output Z is obtained from the connection node of PTr31 and NTr3. This state corresponds to an inverter circuit of the signal of the first input terminal M1 and the output Z turns to the signal M1x, which is the inverted signal of M1.

As is obvious from comparison between FIG. 22B and FIG. 22C, the switch NOR gate SR is a circuit in which the signal of the first input terminal M1 and the signal of the second input terminal M2 are symmetric about the output. In other words, the switch NOR gate SR is a circuit in which the number of transistors from the first input terminal M1 to the output Z and the number of transistors from the second input terminal M2 to the output Z are the same.

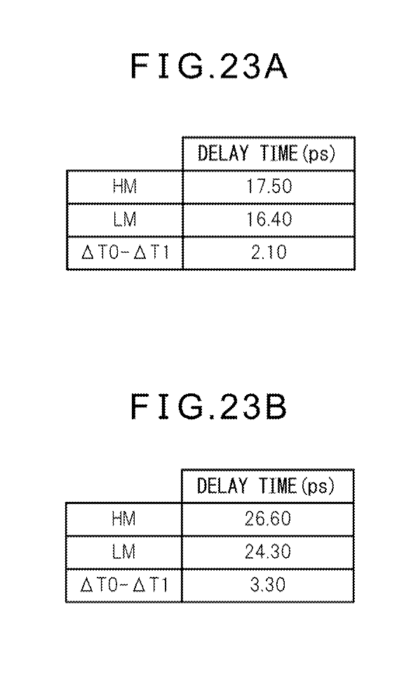

FIG. 23A and FIG. 23B are diagrams illustrating the delay times HM, LM when the switch NOR gate SR in FIG. 20B is manufactured by a typical process, wherein FIG. 23A illustrates the case where the switch NOR gate SR is manufactured by the process with a gate length of 90 nm and FIG. 23B illustrates the case where manufactured by the process with a gate length of 130 nm.

As illustrated in FIG. 23A, by the process with a gate length of 90 nm, HM=17.50 ps and LM=16.40 ps. As illustrated in FIG. 23B, by the process with a gate length of 130 nm, HM=26.60 ps and LM=24.30 ps.

Together with the delay time of the two-input NOR gate illustrated in FIG. 19A and FIG. 19B, in the case illustrated in FIG. 23A, the difference ΔT0−ΔT1 between the change in the delay time ΔT0 between an odd-numbered stage and an even-numbered stage and the change in the delay time ΔT1 between an odd-numbered stage and an even-numbered stage in the variable delay circuit is 2.10 ps. In the case illustrated in FIG. 23B, the difference ΔT0−ΔT1=3.30 ps. This is smaller than the difference ΔT0−ΔT1 in the general variable delay circuit illustrated in FIG. 18A.

A variable delay circuit of a fifth embodiment differs in that the third NOR gate R3 of each delay unit is replaced with a balance NOR gate in the general variable delay circuit having the two-input NOR gate illustrated in FIG. 18A and other parts are the same.

The balance NOR gate has the first input terminal M1 and the second input terminal M2. The first input terminal M1 and the second input terminal M2 are connected in the same manner as the input terminals S and F of the two-input NOR gate in FIG. 18A. Specifically, to the first input terminal M1, the output of the second NOR gate R2 is input. To the second input terminal M2, the output Z of the balance NOR gate of the delay unit in the subsequent stage is input. The output Z of the balance NOR gate in the first stage is the output signal CLKOUT. To the variable delay circuit of the fifth embodiment, the first control data CTN0, CTN1, CTN2, . . . , CTNi, . . . , and the second control data CT0, CT1, CT2, . . . , CTi, . . . , illustrated in FIG. 21 are supplied and the amount of delay may be adjusted.

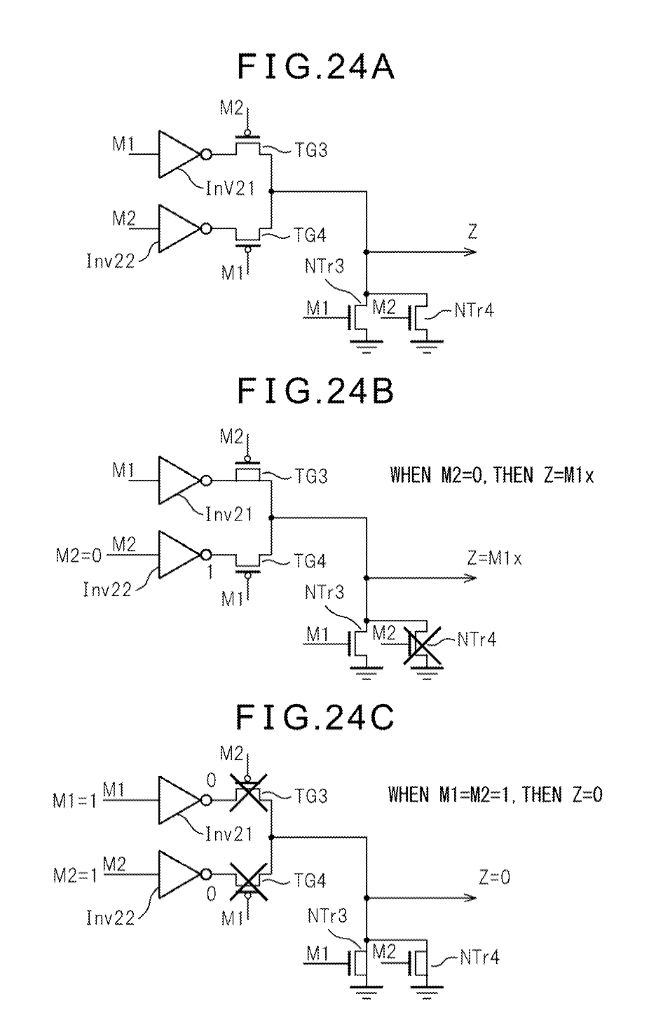

FIG. 24A to FIG. 24C are circuit diagrams of the balance NOR gate and diagrams for explaining the operation thereof.

As illustrated in FIG. 24A, the balance NOR gate has the two N-channel MOS transistors NTr3 and NTr4, two transfer gates TG3 and TG4, and two inverters Inv21 and Inv22.

NTr3 and NTr4 are connected in parallel between the low-potential side power source GND and the output Z and to the gate of NTr3, the signal of the first input terminal M1 is applied and to the gate of NTr4, the signal of the second input terminal M2 is applied. Inv21 receives the signal of the first input terminal M1 and outputs the inverted signal. Inv22 receives the signal of the second input terminal M2 and outputs the inverted signal. TG3 is connected between the output Z and the output of Inv21 and to the gate, the signal of the second input terminal M2 is applied. TG4 is connected between the output Z and the output of Inv22 and to the gate, the signal of the first input terminal M1 is applied. Consequently, when the signal of the second input terminal M2 is at L, the signal of the first input terminal M1 is inverted and output to the output Z and when the signal of the first input terminal M1 is at L, the signal of the second input terminal M2 is inverted and output to the output Z.

When the signal of the second input terminal M2 is at H, in the balance NOR gate, TG3 is in the OFF state as illustrated in FIG. 24B and the output of Inv21 does not affect the output Z. At this time, NTr4 is in the ON state and the output Z turns to L. The output of Inv22 is at L. When the signal of the first input terminal M1 is at H, TG4 is in the OFF state and does not affect the output Z, and when the signal of the first input terminal M1 is at L, TG4 is in the ON state and the output of Inv22 at L is transmitted to the output Z, however, this is not contradictory to the above-mentioned output. When the signal of the first input terminal M1 is at H, NTr3 turns on, however, this is also not contradictory to the above-mentioned output.

FIG. 24B illustrates a case where the signal of the second input terminal M2 is at H, however, this also applies to the case where the signal of the first input terminal M1 is at H.

When both the signal of the first input terminal M1 and the signal of the second input terminal M2 are at L (0), as illustrated in FIG. 24C, NTr3 and NTr4 turn off, TG3 and TG4 turn on, the outputs of Inv21 and Inv22 at H (1) are transmitted to the output Z, and the output Z turns to L (0).

As described above, the balance NOR gate is a circuit in which the signal of the first input terminal M1 and the signal of the second input terminal M2 are symmetric about the output. In other words, the balance NOR gate is a circuit in which the number of transistors from the first input terminal M1 to the output Z and the number of transistors from the second input terminal M2 to the output Z are the same.

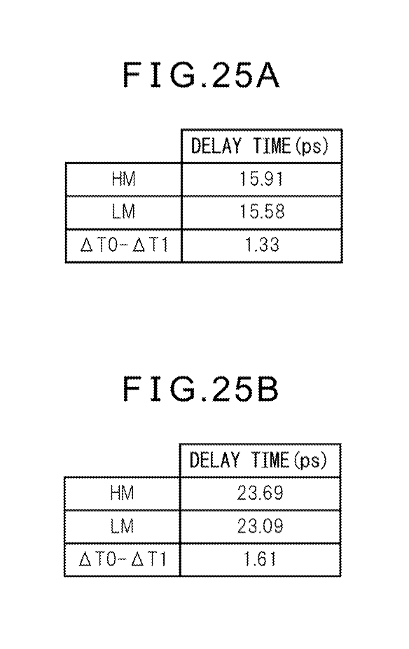

FIG. 25A and FIG. 25B are diagrams illustrating the delay times HM, LM when the balance NOR gate in FIG. 24A is manufactured by a typical process, wherein FIG. 25A illustrates the case where the balance NOR gate is manufactured by the process with a gate length of 90 nm and FIG. 25B illustrates the case where manufactured by the process with a gate length of 130 nm.

As illustrated in FIG. 25A, by the process with a gate length of 90 nm, HM=15.91 ps and LM=15.58 ps. As illustrated in FIG. 25B, by the process with a gate length of 130 nm, HM=23.69 ps and LM=23.09 ps.

Together with the delay time of the two-input NOR gate illustrated in FIG. 19. in the case illustrated in FIG. 25A, the difference ΔT0−ΔT1 between the change in the delay time ΔT0 between an odd-numbered stage and an even-numbered stage and the change in the delay time ΔT1 between an even-numbered stage and an odd-numbered stage in the variable delay circuit is 1.33 ps. In the case illustrated in FIG. 25B, the difference ΔT0−ΔT1=1.61 ps. This is smaller than the difference ΔT0−ΔT1 in the general variable delay circuit illustrated in FIG. 18A.

As explained above, according to the first to fifth embodiments, the gates having substantially the same delay from the two input terminals to the output node are used, and therefore, it is possible to generate the same delay interval and to reduce the error of the variable delay circuit. Due to this, it is possible to improve the adjustment precision of the variable delay circuit.

Further, with the variable delay circuit of the embodiments, an increase in circuit scale and an increase in layout size are small and it is possible to apply a standard CMOS logic circuit designing method to its designing.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A variable delay circuit comprising a plurality of delay units connected in series, wherein
each delay unit includes first to third logic gates,
the first logic gates of the plurality of delay units are connected in series so that the output of the first gate of the previous stage is input to one of inputs of the first gate of the subsequent stage and first control data specifying a return position is input to the other of the inputs of the first gate,
in each stage, one of inputs of the second logic gate is connected to the one of the inputs of the first logic gate and second control data specifying a return position is input to the other of the inputs of the second gate,
the third logic gates of the plurality of delay units are connected in series so that the output of the subsequent stage is one of inputs of the third logic gates of the previous stage and in each stage, the output of the second logic gate is input to the other of the inputs of the third gate, and
in each third logic gate, the delay time of a path from the one of the inputs to the output and the delay time of a path from the other of the inputs to the output are substantially same.

2. The variable delay circuit according to claim 1, wherein the third logic gate outputs an NAND value of the one of the inputs and the other of the inputs.

3. The variable delay circuit according to claim 2, wherein in the third logic gate, the number of transistors in the path from the one of the inputs to the output and the number of transistors in the path from the other of the inputs to the output are same.

4. The variable delay circuit according to claim 3, wherein
the third logic gate comprises:
a first P-channel MOS transistor connected between a high-potential side power source and the output and the one of the inputs of the third logic gate is applied to the gate of the first P-channel MOS transistor;
a second P-channel MOS transistor connected in parallel with the first P-channel MOS transistor and between the high-potential side power source and the output and the other of the inputs of the third logic gate is applied to the gate of the second P-channel MOS transistor;
a first row including first and second N-channel MOS transistors connected in series between the output and a low-potential side power source; and
a second row including third and fourth N-channel MOS transistors connected in parallel with the first row and in series between the output and the low-potential side power source,
the first N-channel MOS transistor in the first row is arranged in a position near to the output,
the third N-channel MOS transistor in the second row is arranged in a position near to the output,
the one of the inputs of the third logic gate is applied to the gate of the first N-channel MOS transistor,
the other of the inputs of the third logic gate is applied to the gate of the third N-channel MOS transistor,
the second control data is applied to the gate of the second N-channel MOS transistor, and
an inverted signal of the second control data is applied to the gate of the fourth N-channel MOS transistor.

5. The variable delay circuit according to claim 3, wherein
the third logic gate comprises:
a first P-channel MOS transistor connected between a high-potential side power source and the output and the one of the inputs of the third logic gate is applied to the gate of the first P-channel MOS transistor;
a second P-channel MOS transistor connected in parallel with the first P-channel MOS transistor and between the high-potential side power source and the output and the other of the inputs of the third logic gate is applied to the gate of the second P-channel MOS transistor;
a first row including a first transfer gate and a first inverter connected in series between the output and the one of the inputs of the third logic gate; and
a second row including a second transfer gate and a second inverter connected in parallel with the first row and in series between the output and the other of the inputs of the third logic gate,
the one of the inputs of the third logic gate is applied to the gate of the second transfer gate and the first inverter,
the other of the inputs of the third logic gate is applied to the gate of the first transfer gate and the second inverter.

6. The variable delay circuit according to claim 2, wherein
the third logic gate comprises:
a first P-channel MOS transistor connected between a high-potential side power source and the output and the one of the inputs of the third logic gate is applied to the gate of the first P-channel MOS transistor;
a second P-channel MOS transistor connected in parallel with the first P-channel MOS transistor and between the high-potential side power source and the output and the other of the inputs of the third logic gate is applied to the gate of the second P-channel MOS transistor;
a first row including first and second N-channel MOS transistors connected in series between the output and a low-potential side power source;
a second row including third and fourth N-channel MOS transistors connected in parallel with the first row and in series between the output and the low-potential side power source; and
a switch selecting either one of the one of the inputs of the third logic gate or the low-potential side power source in response to the second control data to output a selection signal,
the first N-channel MOS transistor in the first row is arranged in a position near to the output,
the third N-channel MOS transistor in the second row is arranged in a position near to the output,
the one of the inputs of the third logic gate is applied to the gate of the first N-channel MOS transistor,
the other of the inputs of the third logic gate is applied to the gate of the second and fourth N-channel MOS transistors,
the selection signal is applied to the gate of the third N-channel MOS transistor.

7. The variable delay circuit according to claim 1, wherein the third logic gate outputs an OR value of the one of the inputs and the other of the inputs.

8. The variable delay circuit according to claim 2, wherein in the third logic gate, the number of transistors in the path from the one of the inputs to the output and the number of transistors in the path from the other of the inputs to the output are same.

9. The variable delay circuit according to claim 8, wherein
the third logic gate comprises:
a first N-channel MOS transistor connected between a low-potential side power source and the output and the one of the inputs of the third logic gate is applied to the gate of the first N-channel MOS transistor;
a second N-channel MOS transistor connected in parallel with the first N-channel MOS transistor and between the low-potential side power source and the output and the other of the inputs of the third logic gate is applied to the gate of the second N-channel MOS transistor;
a first row including first and second P-channel MOS transistors connected in series between the output and a high-potential side power source; and
a second row including third and fourth P-channel MOS transistors connected in parallel with the first row and in series between the output and the high-potential side power source,
the first P-channel MOS transistor in the first row is arranged in a position near to the output,
the third P-channel MOS transistor in the second row is arranged in a position near to the output,
the one of the inputs of the third logic gate is applied to the gate of the first P-channel MOS transistor,
the other of the inputs of the third logic gate is applied to the gate of the third P-channel MOS transistor,
the second control data is applied to the gate of the second P-channel MOS transistor, and
an inverted signal of the second control data is applied to the gate of the fourth P-channel MOS transistor.

10. The variable delay circuit according to claim 8, wherein
the third logic gate comprises:
a first N-channel MOS transistor connected between a low-potential side power source and the output and the one of the inputs of the third logic gate is applied to the gate of the first N-channel MOS transistor;
a second N-channel MOS transistor connected in parallel with the first N-channel MOS transistor and between the low-potential side power source and the output and the other of the inputs of the third logic gate is applied to the gate of the second N-channel MOS transistor;
a first row including a first transfer gate and a first inverter connected in series between the output and the one of the inputs of the third logic gate; and
a second row including a second transfer gate and a second inverter connected in parallel with the first row and in series between the output and the other of the inputs of the third logic gate,
the one of the inputs of the third logic gate is applied to the gate of the second transfer gate and the first inverter,
the other of the inputs of the third logic gate is applied to the gate of the first transfer gate and the second inverter.
